(19) United States
(12) Patent Application Publication
(10) Pub. No.: US 2021/0115565 A1
(43) Pub. Date: Apr. 22, 2021

(54) PLATING METHOD, PLATING APPARATUS AND RECORDING MEDIUM

(71) Applicant: Tokyo Electron Limited, Tokyo (JP)

(72) Inventors: Yuichiro Inatomi, Kikuchi-gun, Kumamoto (JP); Nobutaka Mizutani, Tokyo (JP)

(21) Appl. No.: 16/496,064

(22) PCT Filed: Mar. 22, 2018
(86) PCT No.: PCT/JP2018/011355

§ 371 Date: Sep. 20, 2019

(30) Foreign Application Priority Data
Mar. 23, 2017 (JP) 2017-058014

(51) Int. Cl. C23C 18/16; C23C 18/31; H01L 21/311

(52) U.S. Cl. CPC C23C 18/166; C23C 18/1603; C23C 18/1639; H01L 21/31144; C23C 18/31; H01L 21/31116; C23C 18/1619

(57) ABSTRACT

A plating method includes preparing a substrate having a surface including an adhesive material portion made of a material to which a catalyst easily adheres and a non-adhesive material portion to which the catalyst is difficult to attach; imparting the catalyst to the substrate by supplying a catalyst solution onto the substrate; removing, by supplying a catalyst removing liquid containing a reducing agent onto the substrate, the catalyst from the non-adhesive material portion while allowing the catalyst to be left on a surface of the adhesive material portion; and forming a plating layer selectively on the adhesive material portion by supplying a plating liquid onto the substrate.

### TECHNICAL FIELD

The various aspects and embodiments described herein pertain generally to a plating method, a plating apparatus and a recording medium.

### BACKGROUND

Recently, as miniaturization and three-dimension of semiconductor devices are required, it is required to improve processing accuracy by etching when processing the semiconductor devices. As one way to improve the processing accuracy by etching, it is required to improve accuracy of a hard mask (HM) for dry etching which is formed on a substrate.

In general, however, there are many restrictions for a material of the hard mask. For example, the material of the hard mask needs to have high adhesivity to a substrate and a resist, needs to have high resistance against a heat treatment and an etching processing, and, also, needs to be easily removed. For the reason, only a limited material such as silicon nitride or titanium nitride has been used as the material of the hard mask.

In view of this, the present inventors have examined, on a substrate having, on a surface thereof, a portion formed of silicon oxide (hereinafter, also referred to as “SiO” for simplicity in the present specification) and a portion formed of silicon nitride (hereinafter, also referred to as “SiN” for simplicity in the present specification), applying a Pd catalyst only to a surface of the SiN portion selectively to thereby form a plating layer only on the surface of the SiN portion. The plating layer formed on the surface of the SiN portion can be used as a hard mask, and it is possible to select various kinds of materials as the plating layer depending on requirements therefor.

When performing electroless plating, a catalyst such as Pd, which acts as a nucleus of precipitation of the plating, is applied to a surface of a plating target. If the catalyst is applied to the surface of the substrate including the SiN portion and the SiO portion, the catalyst adheres to the SiO portion, on which the plating layer is not intended to be formed, as well as the SiN portion. Since adhesivity between the catalyst and the SiO is lower than adhesivity between the catalyst and the SiN, most of the catalyst adhering to the surface of the SiO portion is removed through a rinsing processing performed afterwards. However, it is difficult to remove the catalyst on the surface of the SiO portion completely through the rinsing processing. If the catalyst remains on the surface of the SiO portion, there is a concern that the plating layer may be formed as the remaining catalyst may act as the nucleus.

### PRIOR ART DOCUMENT

Patent Document 1: Japanese Patent Laid-open Publication No. 2009-249679

### SUMMARY

In view of foregoing, exemplary embodiments provide a technique of applying a catalyst to a surface of a substrate and efficiently removing the catalyst from a portion of the surface of the substrate which is not required to be plated.

In one exemplary embodiment, a plating method includes preparing a substrate having a surface including an adhesive material portion made of a material to which a catalyst easily adheres and a non-adhesive material portion to which the catalyst is difficult to attach; imparting the catalyst to the substrate by supplying a catalyst solution onto the substrate; removing, by supplying a catalyst removing liquid containing a reducing agent onto the substrate, the catalyst from the non-adhesive material portion while allowing the catalyst to be left on a surface of the adhesive material portion; and forming a plating layer selectively on the adhesive material portion by supplying a plating liquid onto the substrate.

In another exemplary embodiment, there is provided a computer-readable recording medium having stored thereon computer-executable instructions that, in response to execution, cause a plating apparatus to perform the plating method.

In still another exemplary embodiment, a plating apparatus includes a substrate holder configured to hold a substrate; a catalyst imparting device configured to impart a catalyst solution to the substrate; a catalyst removing liquid supply configured to supply a catalyst removing liquid onto the substrate; a plating liquid supply configured to supply a plating liquid onto the substrate; and a controller configured to control the plating apparatus to perform the plating method.

According to the exemplary embodiments, after the catalyst is applied to the surface of the substrate, it is possible to remove the catalyst efficiently from the portion of the surface of the substrate which is not required to be plated. Thus, it is possible to suppress the plating layer from being formed on the portion which is not required to be plated.

### BRIEF DESCRIPTION OF THE DRAWINGS

FIG. 1 is a schematic plan view of a plating apparatus.

FIG. 2 is a schematic cross sectional view illustrating a configuration of a plating unit of the plating apparatus shown in FIG. 1.

FIG. 3 is a schematic cross sectional view illustrating a structure of a substrate on which a plating layer is to be formed by a plating method according to an exemplary embodiment.

FIG. 4A to FIG. 4E are schematic cross sectional views illustrating a manufacturing method for the substrate on which the plating layer is to be formed by the plating method.

FIG. 5 is a flowchart of the plating method.

FIG. 6A and FIG. 6B are schematic cross sectional views illustrating the plating method according to the exemplary embodiment.

FIG. 7A to FIG. 7C are schematic cross sectional views illustrating a method of processing the substrate on which the plating layer is formed by the plating method according to the present exemplary embodiment.

FIG. 8A to FIG. 8C are schematic diagrams illustrating an operation in which a catalyst particle is removed from a non-adhesive material portion 31 of the substrate.

### DETAILED DESCRIPTION

Hereinafter, exemplary embodiments will be described with reference to the accompanying drawings.

<Configuration of Plating Apparatus>

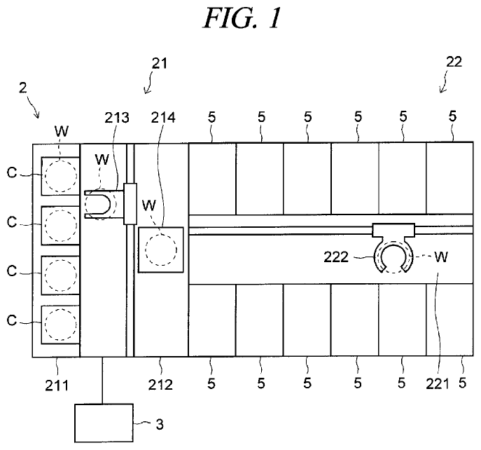

Referring to FIG. 1, a configuration of a plating apparatus according to an exemplary embodiment will be explained. FIG. 1 is a schematic diagram illustrating the configuration of the plating apparatus according to the exemplary embodiment.

As depicted in FIG. 1, a plating apparatus 2 according to the present exemplary embodiment is equipped with a controller 3 configured to control an operation of the plating apparatus 2.

The plating apparatus 2 is configured to perform various processings on a substrate. The various processings performed by the plating apparatus 2 will be discussed later.

The controller 3 is implemented by, for example, a computer, and includes an operation controller and a storage unit. The operation controller is implemented by, for example, a CPU (Central Processing Unit) and is configured to control an operation of the plating apparatus 2 by reading and executing the programs stored in the storage unit. The storage unit is implemented by a memory device such as, but not limited to, a RAM (Random Access Memory), a ROM (Read Only Memory) or a hard disk, and stores thereon programs for controlling various processings performed in the plating apparatus 2. Further, the programs may be recorded in a computer-readable recording medium, or may be installed from the recording medium to the storage unit. The computer-readable recording medium may be, for example, a hard disc (HD), a flexible disc (FD), a compact disc (CD), a magnet optical disc (MO), or a memory card. Stored in the recording medium is a program which, when executed by a computer for controlling an operation of the plating apparatus 2, allows the computer to control the plating apparatus 2 to perform a plating method to be described later.

<Configuration of Plating Unit>

Referring to FIG. 1, a configuration of the plating apparatus 2 will be discussed. FIG. 1 is a schematic plan view illustrating the configuration of the plating unit 2.

The plating apparatus 2 includes a carry-in/out station 21 and a processing station 22 which is provided adjacent to the carry-in/out station 21.

The carry-in/out station 21 is equipped with a placing section 211 and a transfer section 212 which is provided adjacent to the placing section 211.

In the placing section 211, transfer containers (hereinafter, referred to as “carriers C”) for accommodating therein a plurality of substrates W horizontally are placed.

The transfer section 212 is equipped with a transfer device 213 and a delivery unit 214. The transfer device 213 is provided with a holding mechanism configured to hold a substrate W and is configured to be movable horizontally and vertically and pivotable around a vertical axis.

The processing station 22 includes plating units 5. In the present exemplary embodiment, the number of the plating units 5 belonging to the processing station 22 is two or more. However, only one plating unit 5 may be provided. The plating units 5 are arranged at both sides of a transfer path 221 which extends in a preset direction.

A transfer device 222 is provided in the transfer path 221. The transfer device 222 is equipped with a holding mechanism configured to hold the substrate W and is configured to be movable horizontally and vertically and pivotable around a vertical axis.

In the plating apparatus 2, the transfer device 213 of the carry-in/out station 21 is configured to transfer the substrate W between the carrier C and the delivery unit 214. To elaborate, the transfer device 213 takes out the substrate W from the carrier C which is placed in the placing section 211, and places the substrate W in the delivery unit 214. Further, the transfer device 213 takes out the substrate W which is placed in the delivery unit 214 by the transfer device 222 of the processing station 22, and accommodates the substrate W back into the carrier C on the placing section 211.

In the plating apparatus 2, the transfer device 222 of the processing station 22 is configured to transfer the substrate W between the delivery unit 214 and the plating unit 5 and between the plating unit 5 and the delivery unit 214. To elaborate, the transfer device 222 takes out the substrate W which is placed in the delivery unit 214 and then carries the substrate W into the plating unit 5. Further, the transfer device 222 takes out the substrate W from the plating unit 5 and places the substrate W in the delivery unit 214.

<Configuration of Plating Unit>

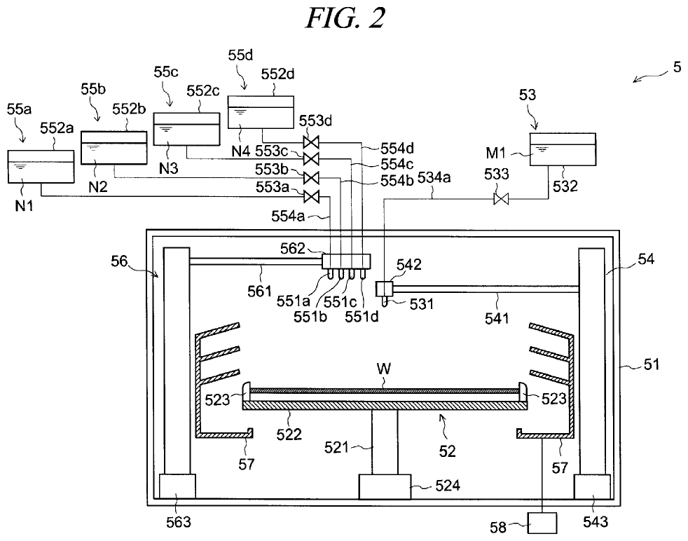

Now, referring to FIG. 2, a configuration of the plating unit 5 will be explained. FIG. 2 is a schematic cross sectional view illustrating the configuration of the plating unit 5.

The plating unit 5 is configured to perform a plating processing on a substrate W having a surface including a non-adhesive material portion 31 and an adhesive material portion 32, and configured to form a plating layer 35 selectively on the adhesive material portion 32 (details of this plating processing will be described later). The adhesive material portion 32 refers to a portion made of a material to which a catalyst is difficult to attach. The non-adhesive material portion 31 refers to a portion made of a material to which the catalyst easily adheres. A substrate processing performed by the plating unit 5 includes a catalyst imparting processing and an electroless plating processing at least. However, the substrate processing may include other processings besides the catalyst imparting processing and the plating processing.

The plating unit 5 includes a chamber 51; a substrate holder 52 provided within the chamber 51 and configured to hold the substrate W; and a plating liquid supply 53 configured to supply a plating liquid M1 to the substrate W held by the substrate holder 52.

The substrate holder 52 includes a rotation shaft 521 extending in a vertical direction within the chamber 51; a turntable 522 provided at an upper end portion of the rotation shaft 521; a chuck 523 provided on an outer peripheral portion of a top surface of the turntable 522 and configured to support an edge portion of the substrate W; and a driving unit 524 configured to rotate the rotation shaft 521.

The substrate W is supported by the chuck 523 to be horizontally held by the turntable 522 while being slightly spaced apart from the top surface of the turntable 522. In the present exemplary embodiment, a mechanism of holding the substrate W by the substrate holder 52 is of a so-called mechanical chuck type in which the edge portion of the substrate W is held by the chuck 523 which is configured to be movable. However, a so-called vacuum chuck type in which a rear surface of the substrate W is vacuum-attracted may be used instead.

A base end portion of the rotation shaft 521 is rotatably supported by the driving unit 524, and a leading end portion of the rotation shaft 521 sustains the turntable 522 horizontally. If the rotation shaft 521 is rotated, the turntable 522 placed on the upper end portion of the rotation shaft 521 is rotated, and, as a result, the substrate W which is held by the turntable 522 with the chuck 523 is also rotated.

The plating liquid supply 53 is equipped with a nozzle 531 configured to discharge the plating liquid M1 onto the substrate W held by the substrate holder 52; and a plating liquid source 532 configured to supply the plating liquid M1 to the nozzle 531. The plating liquid M1 is stored in a tank of the plating liquid source 532, and the plating liquid M1 is supplied into the nozzle 531 from the plating liquid source 532 through a supply passageway 534 which is equipped with a flow rate controller such as a valve 533.

The plating liquid M1 is a plating liquid for an autocatalytic (reduction) electroless plating. The plating liquid M1 contains a metal ion such as a cobalt (Co) ion, a nickel (Ni) ion, or a tungsten (W) ion; and a reducing agent such as hypophosphorous acid or dimethylamineborane. Further, in the autocatalytic (reduction) electroless plating, the metal ion in the plating liquid M1 is reduced by electrons emitted in an oxidation reaction of the reducing agent in the plating liquid M1 to be precipitated as a metal, so that a metal film (plating film) is formed. The plating liquid M1 may further contain an additive or the like. The metal film (plating film) formed by the plating processing with the plating liquid M1 may be, by way of non-limiting example, CoB, CoP, CoWP, CoWB, CoWBP, NiWB, NiB, NiWP, NiWBP, or the like. P (phosphorus) in the metal film (plating film) is originated from the reducing agent (e.g., hypophosphorous acid) containing P, and B (boron) in the plating film is originated from the reducing agent (e.g., dimethylamineborane) containing B.

The nozzle 531 is connected to a nozzle moving device 54. The nozzle moving device 54 is configured to drive the nozzle 531. The nozzle moving device 54 includes an arm 541, a moving body 542 which is configured to be movable along the arm 541 and has a driving mechanism embedded therein; and a rotating/elevating device 543 configured to rotate and move the arm 541 up and down. The nozzle 531 is provided at the moving body 542. The nozzle moving device 54 is capable of moving the nozzle 531 between a position above a center of the substrate W held by the substrate holder 52 and a position above a periphery of the substrate W, and is also capable of moving the nozzle 531 up to a stand-by position outside a cup 57 to be described later when viewed from the top.

Within the chamber 51, there are arranged a catalyst solution supply (catalyst imparting device) 55a, a cleaning liquid supply 55b, and a rinse liquid supply 55c configured to supply a catalyst solution N1, a cleaning liquid N2, and a rinse liquid N3 onto the substrate W held by the substrate holder 52, respectively. Further, a catalyst removing liquid supply 55d is also provided within the chamber 51.

The catalyst solution supply (catalyst imparting device) 55a includes a nozzle 551a configured to discharge the catalyst solution N1 onto the substrate W held by the substrate holder 52; and a catalyst solution source 552a configured to supply the catalyst solution N1 to the nozzle 551a. The catalyst solution N1 is stored in a tank of the catalyst solution source 552a, and the catalyst solution N1 is supplied to the nozzle 551a from the catalyst solution source 552a through a supply passageway 554a which is provided with a flow rate controller such as a valve 553a.

The cleaning liquid supply 55b includes a nozzle 551b configured to discharge the cleaning liquid N2 onto the substrate W held by the substrate holder 52; and a cleaning liquid source 552b configured to supply the cleaning liquid N2 to the nozzle 551b. The cleaning liquid N2 is stored in a tank of the cleaning liquid source 552b, and the cleaning liquid N2 is supplied to the nozzle 551b from the cleaning liquid source 552b through a supply passageway 554b which is provided with a flow rate controller such as a valve 553b.

The rinse liquid supply 55c includes a nozzle 551c configured to discharge the rinse liquid N3 onto the substrate W held by the substrate holder 52; and a rinse liquid source 552c configured to supply the rinse liquid N3 to the nozzle 551c. The rinse liquid N3 is stored in a tank of the rinse liquid source 552c, and the rinse liquid N3 is supplied to the nozzle 551c from the rinse liquid source 552c through a supply passageway 554c which is provided with a flow rate controller such as a valve 553c.

The catalyst removing liquid supply 55d is equipped with a nozzle 551d configured to discharge the catalyst removing liquid N4 onto the substrate W held by the substrate holder 52; and a catalyst removing liquid source 552d configured to supply the catalyst removing liquid N4 to the nozzle 551d. The catalyst removing liquid N4 is stored in a tank of the catalyst removing liquid source 552d, and the catalyst removing liquid N4 is supplied to the nozzle 551d from the catalyst removing liquid source 552d through a supply passageway 554d which is provided with a flow rate controller such as a valve 553d.

The catalyst solution N1 contains a metal catalyst in the form of particles, more particularly, nanoparticles. To elaborate, the catalyst solution N1 includes a metal catalyst in the form of nanoparticles, a dispersant, and water as a dispersion medium. This metal catalyst in the form of nanoparticles may be, by way of non-limiting example, palladium (Pd) in the form of nanoparticles. The dispersant serves to allow the metal catalyst in the form of nanoparticles to be easily dispersed in the catalyst solution N1. The dispersant may be, by way of non-limiting example, polyvinylpyrrolidone (PVP). The metal catalyst needs to have sufficient catalytic activity to the oxidation reaction of the reducing agent contained in the plating liquid M1. By way of non-limiting example, such a metal catalyst may include, besides the aforementioned Pd, iron group elements (Fe, Co, Ni), platinum group elements (Ru, Rh, Os, Ir, Pt), Cu, Ag or Au. The catalyst solution N1 may further include an adsorption accelerator configured to accelerate adsorption of the catalyst to a surface of a material to which the catalyst is imparted.

As an example of the cleaning liquid N2, an organic acid such as a formic acid, malic acid, a succinic acid, a citric acid or a malonic acid, or hydrofluoric acid (DHF) (aqueous solution of hydrogen fluoride) diluted to the extent that it does not corrode the plating target surface of the substrate may be used.

As an example of the rinse liquid N3, pure water may be used.

As an example of the catalyst removing liquid N4, a reducing agent, desirably, the same reducing agent as the reducing agent contained in the plating liquid M1 may be used. Such a reducing agent may be, by way of example, but not limitation, the aforementioned dimethylamineborane (DMAB). The DMAB is used as the catalyst removing liquid N4 after being diluted to about 100 times to about 1000 times with, for example, DIW (pure water).

The plating unit 5 includes a nozzle moving device 56 configured to move the nozzles 551a to 551c. The nozzle moving device 56 is equipped with an arm 561; a moving body 562 which is configured to be movable along the arm 561 and has a moving mechanism embedded therein; and a rotating/elevating device 563 configured to rotate and move the arm 561 up and down. The nozzles 551a to 551c are provided at the moving body 562. The nozzle moving device 56 is capable of moving the nozzles 551a to 551c between a position above the central portion of the substrate W held by the substrate holder 52 and a position above the peripheral portion of the substrate W, and also capable of moving the nozzles 551a to 551c up to a stand-by position outside the cup 57 to be described later when viewed from the top. In the present exemplary embodiment, though the nozzles 551a to 551c are held by the common arm, they may be configured to be held by different arms and moved independently.

The cup 57 is disposed around the substrate holder 52. The cup 57 is configured to receive various kinds of processing liquids (e.g., the catalyst solution, the plating liquid, the cleaning liquid, the rinse liquid, the catalyst removing liquid, etc.) scattered from the substrate W and drain the received processing liquids to the outside of the chamber 51. The cup 57 is equipped with an elevating device 58 configured to move the cup 57 up and down.

<Structure of Substrate>

Now, a structure of the substrate on which the plating layer is to be formed by the plating method according to the present exemplary embodiment will be explained.

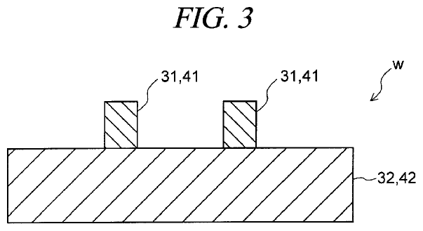

As depicted in FIG. 3, the surface of the substrate W on which the plating layer 35 is to be formed includes the non-adhesive material portion 31 made of the material to which the catalyst is difficult to attach and the adhesive material portion 32 made of the material to which the catalyst easily adheres. There is no specific limitation in the structure of the non-adhesive material portion 31 and the adhesive material portion 32 as long as they are exposed at the surface of the substrate W. In the present exemplary embodiment, the substrate W includes a base member 42 made of the adhesive material portion 32 and a core member 41 which is protruded from the base member 42 and is made of the non-adhesive material portion 31 having a pattern shape.

For example, the non-adhesive material portion 31 is made of a material containing SiO₂ as a main component, and the adhesive material portion 32 is made of a material containing SiN as a main component. Mostly, the catalyst does not adhere to a surface of the SiO₂ portion. However, there is still a chance for the catalyst to adhere to the surface of the SiO₂ portion slightly. Since the catalyst (herein, Pd) is attracted to N atoms contained in the SiN, the catalyst easily adheres to a surface of the SiN portion.

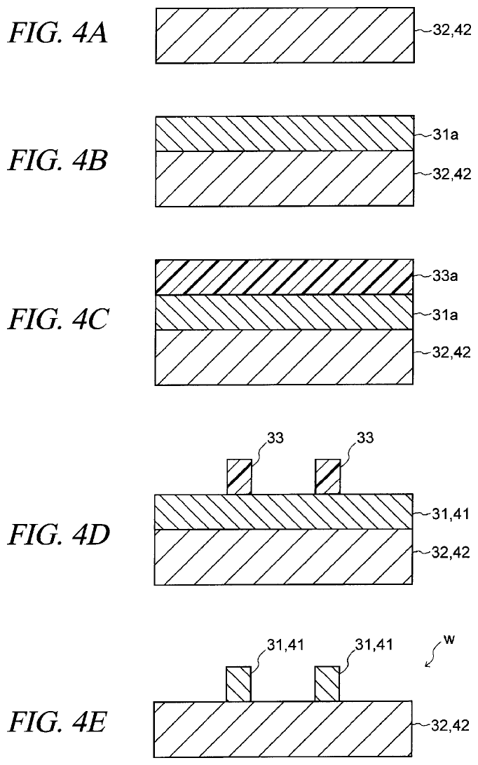

Now, a method of producing the substrate W shown in FIG. 3 will be explained with reference to FIG. 4A to FIG. 4E. To produce the substrate W shown in FIG. 3, the base member 42 made of the adhesive material portion 32 is first prepared, as illustrated in FIG. 4A.

Thereafter, as depicted in FIG. 4B, a film of a material 31a, which forms the non-adhesive material portion 31, is formed on the entire surface of the base member 42 made of the adhesive material portion 32 by a CVD method, a PVD method or the like. The material 31a is composed of, for example, the material containing SiO₂ as the main component.

Subsequently, as illustrated in FIG. 4C, a photosensitive resist 33a is coated on the entire surface of the material 31a forming the non-adhesive material portion 31 and then is dried. Then, by exposing the photosensitive resist 33a through a photo mask and developing it, a resist film 33 having a required pattern is formed, as shown in FIG. 4D.

Afterwards, as depicted in FIG. 4E, the material 31a is dry-etched by using the resist film 33 as a mask. As a result, the core member 41 made of the non-adhesive material portion 31 is patterned to have substantially the same shape as the pattern shape of the resist film 33. Then, by removing the resist film 33, there is obtained the substrate W having the non-adhesive material portion 31 and the adhesive material portion 32 formed on the surface thereof.

<Plating Method>

Now, the plating method using the plating apparatus 1 will be discussed. The plating method performed by plating apparatus 1 includes a plating processing upon the aforementioned substrate W. The plating processing is performed by the plating unit 5. An operation of the plating unit 5 is controlled by the controller 3.

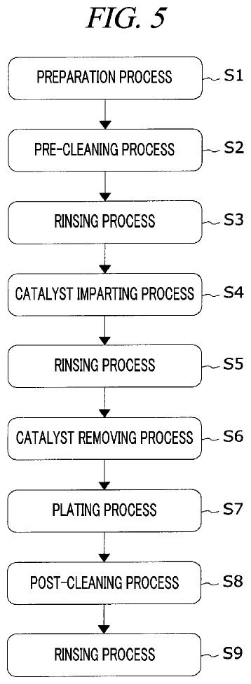

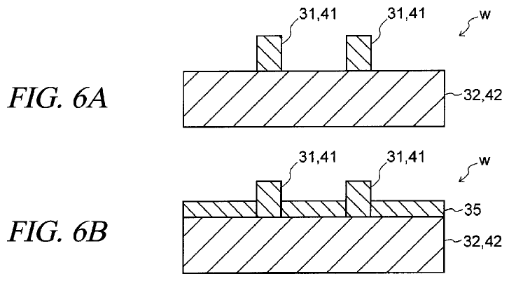

First, the substrate W having the non-adhesive material portion 31 and the adhesive material portion 32 formed on the surface thereof is prepared by performing the above-described method of FIG. 4A to FIG. 4E (preparation process: process S1 of FIG. 5) (see FIG. 6A).

The prepared substrate W is then carried into the plating unit 5 and is held by the substrate holder 52 (see FIG. 2). In the meanwhile, the controller 3 controls the elevating device 58 to move the cup 57 down to a preset position. Then, the controller 3 controls the transfer device 222 to place the substrate W on the substrate holder 52. The substrate W is horizontally placed on the turntable 522 while its periphery portion is held by the chuck 523.

Then, the substrate W held by the substrate holder 52 is cleaned (pre-cleaning process: process S2 of FIG. 5). At this time, while controlling the driving unit 524 to rotate the substrate W held by the substrate holder 52 at a preset speed, the controller 3 controls the cleaning liquid supply 55b to locate the nozzle 551b at a position above the substrate W and to supply the cleaning liquid N2 onto the substrate W from the nozzle 551b. The cleaning liquid N2 supplied onto the substrate W is diffused on the surface of the substrate W by a centrifugal force which is caused by the rotation of the substrate W. As a result, a deposit or the like adhering to the substrate W is removed from the substrate W. The cleaning liquid N2 scattered from the substrate W is drained through the cup 57.

Subsequently, the substrate W after being cleaned is rinsed (rinsing process: process S3 of FIG. 5). At this time, while controlling the driving unit 524 to rotate the substrate W held by the substrate holder 52 at a preset speed, the controller 3 controls the rinse liquid supply 55c to locate the nozzle 551c at a position above the substrate W and to supply the rinse liquid N3 onto the substrate W from the nozzle 551c. The rinse liquid N3 supplied onto the substrate W is diffused on the surface of the substrate W by the centrifugal force which is caused by the rotation of the substrate W. As a result, the cleaning liquid N2 remaining on the substrate W is washed away. The rinse liquid N3 scattered from the substrate W is drained through the cup 57.

Thereafter, a catalyst imparting processing is performed on the substrate W (catalyst imparting process: process S4 of FIG. 5). At this time, while controlling the driving unit 524 to rotate the substrate W held by the substrate holder 52 at a preset speed, the controller 3 controls the catalyst solution supply 55a to locate the nozzle 551a at a position above the substrate W and to supply the catalyst solution N1 onto the substrate W from the nozzle 551a. The catalyst solution N1 supplied onto the substrate W is diffused on the surface of the substrate W by the centrifugal force which is caused by the rotation of the substrate W. The catalyst solution N1 scattered from the substrate W is drained through the cup 57.

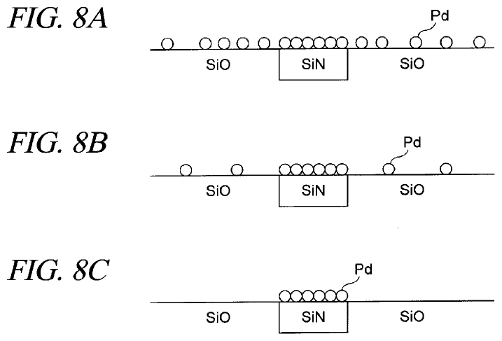

Through the catalyst imparting processing, the catalyst adheres to the entire surface of the substrate W (both the non-adhesive material portion 31 and the adhesive material portion 32) (though adhesion strengths are different) (see FIG. 8A). The catalyst (e.g., Pd) contained in the catalyst solution N1 has high adsorption property with respect to the material (e.g., SiN) forming the adhesive material portion 32, whereas the catalyst is difficult to adsorb to the material (e.g., SiO₂) forming the non-adhesive material portion 31.

Thereafter, a rinsing processing is performed on the substrate W after being cleaned (rinsing process: process S5 of FIG. 5). This rinsing processing is performed in the same way as the aforementioned process S3. Through this rinsing processing, most of the catalyst attached to the surface of the non-adhesive material portion 31 is washed away. Even if the adhesivity (adsorption property) of the catalyst to the non-adhesive material portion 31 is low, however, a small amount of the catalyst may remain on (still adheres to) the surface of the non-adhesive material portion 31 (see FIG. 8B). This remaining catalyst may act as a nucleus of precipitation in a plating process. That is, in the plating process, an undesirable (unintended) plating may be precipitated on the surface of the non-adhesive material portion 31.

To remove the catalyst from the surface of the non-adhesive material portion 31, a catalyst removing processing is performed on the substrate W after being rinsed (catalyst removing process: process S6 of FIG. 5). At this time, while controlling the driving unit 524 to rotate the substrate W held by the substrate holder 52 at a preset speed, the controller 3 controls the catalyst removing liquid supply 55d to locate the nozzle 551d at a position above the substrate W and to supply the catalyst removing liquid N4 onto the substrate W from the nozzle 551d. The catalyst removing liquid N4 supplied onto the substrate W is diffused on the surface of the substrate W by the centrifugal force which is caused by the rotation of the substrate W. Accordingly, all or most of the catalyst having adhered to the non-adhesive material portion 31 is washed away (that is, to the extent that the plating is not formed in the subsequent plating processing). The catalyst removing liquid N4 scattered from the substrate W is drained through the cup 57. Meanwhile, though the catalyst is also removed from the surface of the adhesive material portion 32 to some degree, the amount of the catalyst remaining on the adhesive material portion 32 is enough not to cause any failure in the formation of the plating in the subsequent plating processing (see FIG. 8C).

In case of using the DMAB diluted to about 100 times to about 1000 times with DIW (pure water) as the catalyst removing liquid N4, a time during which the catalyst removing liquid N4 is supplied onto the substrate W from the nozzle 551d only needs to be a short time of, e.g., 10 seconds.

Further, after performing the catalyst imparting processing by using the Pd catalyst in the form of nanoparticles, the dispersant composed of the polyvinylpyrrolidone (PVP) and the catalyst solution N1 containing pure water, as a result of performing the catalyst removing processing for about 10 seconds by using the DMAB diluted to about 100 times to 1000 times with the pure water as the catalyst removing liquid N4, it is found out that the Pd nanoparticles adhering to the non-adhesive material portion 31 made of SiO₂ can be removed and the amount of the Pd nanoparticles remaining on the surface of the adhesive material portion 32 made of SiN is enough not to cause any problem in the plating processing.

A mechanism by which the Pd catalyst in the form of nanoparticles can be removed with the aforementioned catalyst removing liquid N4 is not clearly investigated. However, the present inventors have made conjectures as follows.

(1) Surfaces of the Pd nanoparticles in an oxidation state are reduced by an action of the reducing agent, and sizes of the nanoparticles are reduced to be lifted off the substrate W.

(2) A hydrogen gas is generated by a decomposition reaction of the reducing agent on the surfaces of the Pd nanoparticles, and the catalyst nanoparticles are lifted off while being surrounded by air bubbles (by buoyancy).

(3) The aforementioned phenomena (1) and (2) both take place.

After the completion of the above-stated catalyst removing processing and before the plating processing to be described below, a rinsing processing may be performed on the substrate W. If, however, the component of the catalyst removing liquid used in the catalyst removing processing does not have an adverse influence on the plating liquid, this rinsing processing can be omitted. By way of example, when the DMAB diluted to about 100 time to about 1000 times with the DIW (pure water) is used as the catalyst removing liquid N4 and the DMAB is included in the plating liquid M1 as the reducing agent, the rinsing processing can be omitted.

After the catalyst is removed from the non-adhesive material portion 31, the plating processing is performed on the substrate W (plating process: process S7 of FIG. 5). At this time, while controlling the driving unit 524 to rotate the substrate W held by the substrate holder 52 at a preset speed or while maintaining the substrate W held by the substrate holder 52 stopped, the controller 3 controls the plating liquid supply 53 to locate the nozzle 531 at a position above the substrate W and to supply the plating liquid M1 onto the substrate W from the nozzle 531. As a result, the plating metal is selectively precipitated on the adhesive material portion 32 of the substrate W (specifically, on the catalyst adhering to the surface of the adhesive material portion 32), so that the plating layer 35 is formed. Meanwhile, since the catalyst does not substantially exist on the non-adhesive material portion 31 of the substrate W, no plating metal is precipitated on the non-adhesive material portion 31, so that no plating layer 35 is formed on the non-adhesive material portion 31 (see FIG. 6B).

After the plating processing as described above is completed, the substrate W held by the substrate holder 52 is cleaned (post-cleaning process: process S8 of FIG. 5). At this time, while controlling the driving unit 524 to rotate the substrate W held by the substrate holder 52 at a preset speed, the controller 3 controls the cleaning liquid supply 55b to locate the nozzle 551b at the position above the substrate W and to supply the cleaning liquid N2 onto the substrate W from the nozzle 551b. The cleaning liquid N2 supplied onto the substrate W is diffused on the surface of the substrate W by the centrifugal force which is caused by the rotation of the substrate W. Accordingly, the abnormal plating film or the reaction by-product adhering to the substrate W is removed from the substrate W. The cleaning liquid N2 scattered from the substrate W is drained through the cup 57.

Then, while controlling the driving unit 524 to rotate the substrate W held by the substrate holder 52 at a preset speed, the controller 3 controls the rinse liquid supply 55c to locate the nozzle 551c at the position above the substrate W and to supply the rinse liquid N3 onto the substrate W from the nozzle 551c (rinsing process: process S9 of FIG. 5). Accordingly, the plating liquid M1, the cleaning liquid N2 and the rinse liquid N3 on the substrate W are scattered from the substrate W by the centrifugal force which is caused by the rotation of the substrate W, and are drained through the cup 57.

Thereafter, the substrate W on which the plating layer 35 is formed is carried out of the plating unit 5. At this time, the controller 3 controls the transfer device 222 to take out the substrate W from the plating unit 5 and place the taken-out substrate W in the delivery unit 214. Then, the controller 3 controls the transfer device 213 to take out the substrate W placed in the delivery unit 214 and to carry the substrate W into the carrier C in the placing section 211.

Then, the substrate W is etched by using the plating layer 35 as a hard mask.

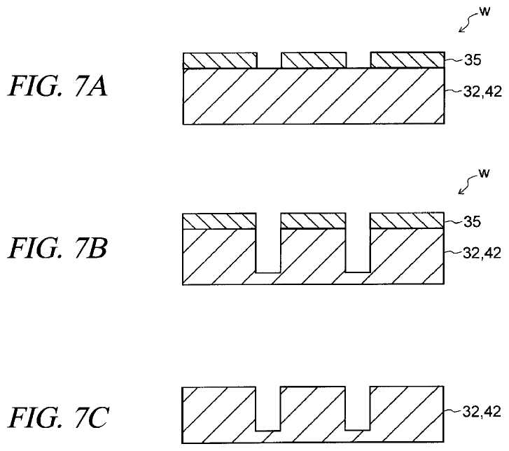

In this case, the non-adhesive material portion 31 is first removed selectively from the substrate W which is taken out of the plating unit 5 (FIG. 7A). Meanwhile, the plating layer 35 formed on the adhesive material portion 32 remains without being removed.

Subsequently, as shown in FIG. 7B, the base member 42 made of the adhesive material portion 32 is dry-etched by using the plating layer 35 as a hard mask. Accordingly, the portion of the base member 42 which is not covered with the plating layer 35 is etched to a preset depth, and recesses having a pattern shape are formed.

Afterwards, by removing the plating layer 35 through a wet cleaning method, the base member 42 provided with the recesses having the pattern shape is obtained, as illustrated in FIG. 7C. Since the plating layer 35 can be removed by the wet cleaning method, it is easy to remove the plating layer 35. An acidic solvent is employed as a chemical liquid used in this wet cleaning method.

Although the various exemplary embodiments have been described so far, those exemplary embodiments are not limiting and can be modified in various ways without departing from the technical conception and essence of the present disclosure. Further, the constituent components described in the above exemplary embodiments may be combined appropriately to produce various other embodiments, and may be partially deleted in various ways. Further, the constituent components in the different exemplary embodiments may be appropriately combined.

A pH adjuster such as, but not limited to, PMA (polymethylacrylate) may be added into the catalyst removing liquid N4, so the catalyst removing liquid N4 may be adjusted to be alkaline. Since surfaces of various members tend to be negatively charged in the alkaline cleaning liquid, re-adhesion of once removed materials in the form of particles (Pd particles, etc.) to the substrate can be suppressed.

In the above-described exemplary embodiments, the liquid contained in the catalyst removing liquid N4 is the DMAB. However, this liquid is not limited thereto. By way of example, if a reducing agent including P (phosphorous), e.g., hypophosphorous acid, is contained in the plating liquid M1, the hypophosphorous acid diluted with pure water may be used as the catalyst removing liquid N4. In such a case, the rinsing processing need not be performed between the catalyst removing processing and the plating processing.

In the above-described exemplary embodiments, the adhesive material portion 32 is made of silicon nitride, and the non-adhesive material portion 31 is made of silicon oxide. However, the exemplary embodiments are not limited thereto. The adhesive material portion 32 may be made of any one of (1) a material containing at least one of a OCHₓ group or a NHₓ group; (2) a metal material containing a Si-based material as a main component; (3) a material containing a catalyst metal material as a main component; and (4) a material containing carbon as a main component. The material (1) may be a material containing a Si—OCHₓ group or a Si—NHₓ group such as SiOCH or SiN. The material (2) may be, by way of non-limiting example, B-doped or P-doped poly-Si, poly-Si, or Si.

### EXPLANATION OF CODES

2: Plating apparatus
3: Controller
5: Plating unit
31: Non-adhesive material portion
32: Adhesive material portion
41: Core member
42: Base member
52: Substrate holder
53: Plating liquid supply
55a: Catalyst solution supply
55b: Cleaning liquid supply
55c: Rinse liquid supply
55d: Catalyst removing liquid supply

We claim:

1. A plating method, comprising:
preparing a substrate having a surface including an adhesive material portion made of a material to which a catalyst easily adheres and a non-adhesive material portion to which the catalyst is difficult to attach;
imparting the catalyst to the substrate by supplying a catalyst solution onto the substrate;
removing, by supplying a catalyst removing liquid containing a reducing agent onto the substrate, the catalyst from the non-adhesive material portion while allowing the catalyst to be left on a surface of the adhesive material portion; and
forming a plating layer selectively on the adhesive material portion by supplying a plating liquid onto the substrate.

2. The plating method of claim 1,
wherein the plating liquid is an electroless plating liquid containing a reducing agent, and the catalyst removing liquid contains the same reducing agent as the reducing agent contained in the electroless plating liquid.

3. The plating method of claim 2,
wherein the catalyst removing liquid is prepared by diluting the reducing agent contained in the electroless plating liquid with pure water.

4. The plating method of claim 2,
wherein the reducing agent contained in the electroless plating liquid is dimethylamineborane (DMAB).

5. The plating method of claim 2,
wherein the forming of the plating layer is performed without performing a rinsing processing of removing the catalyst removing liquid from the substrate after performing the removing of the catalyst.

6. The plating method of claim 1,
wherein the catalyst removing liquid is alkaline.

7. The plating method of claim 1,
wherein the non-adhesive material portion is made of silicon oxide as a main component, and the adhesive material portion is made of silicon nitride as a main component.

8. The plating method of claim 1,
wherein the substrate includes a base member made of the adhesive material portion and a core member which is protruded from the base member and is made of the non-adhesive material portion.

9. A computer-readable recording medium having stored thereon computer-executable instructions that, in response to execution, cause a plating apparatus to perform a plating method as claimed in claim 1.

10. A plating apparatus, comprising:
a substrate holder configured to hold a substrate;
a catalyst imparting device configured to impart a catalyst solution to the substrate;
a catalyst removing liquid supply configured to supply a catalyst removing liquid onto the substrate;
a plating liquid supply configured to supply a plating liquid onto the substrate; and
a controller configured to control the plating apparatus to perform a plating method as claimed in claim 1.
